(19) United States
(12) Patent Application Publication
(10) Pub. No.: US 2025/0357246 A1
(43) Pub. Date: Nov. 20, 2025

(54) SEMICONDUCTOR PACKAGE AND METHOD

(71) Applicant: Taiwan Semiconductor Manufacturing Co., Ltd., Hsinchu (TW)

(72) Inventors: Ban-Li Wu, Hsinchu (TW); Tsung-Hsien Chiang, Hsinchu (TW); Tzu-Sung Huang, Tainan City (TW); Chao-Hsien Huang, Kaohsiung City (TW); Chia-Lun Chang, Tainan City (TW); Hsiu-Jen Lin, Zhubei City (TW); Ming Hung Tseng, Toufen Township (TW); Hao-Yi Tsai, Hsinchu (TW)

(21) Appl. No.: 19/279,629

(22) Filed: Jul. 24, 2025

Related U.S. Application Data
(62) Division of application No. 17/809,039, filed on Jun. 27, 2022.

(51) Int. Cl. H01L 23/367; H01L 21/48; H01L 23/00; H01L 23/373; H01L 23/498; H01L 25/16

(52) U.S. Cl. CPC H01L 23/3677; H01L 21/4857; H01L 21/486; H01L 23/3735; H01L 23/49822; H01L 23/49833; H01L 23/49838; H01L 25/16; H01L 23/49816; H01L 24/16; H01L 24/32; H01L 24/73; H01L 2224/16235; H01L 2224/32225; H01L 2224/73204; H01L 2224/73253; H01L 2924/3511; H01L 2924/35121

(57) ABSTRACT

A semiconductor package including one or more heat dissipation systems and a method of forming are provided. The semiconductor package may include one or more integrated circuit dies, an encapsulant surrounding the one or more integrated circuit dies, a redistribution structure over the one or more integrated circuit dies and the encapsulant. The redistribution structure may include one or more heat dissipation systems, which are electrically isolated from remaining portions of the redistribution structure. Each heat dissipation system may include a first metal pad, a second metal pad, and one or more metal vias connecting the first metal pad to the second metal pad.

### CROSS-REFERENCE TO RELATED APPLICATIONS

This application is a divisional of U.S. patent application Ser. No. 17/809,039, filed Jun. 27, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die in accordance with some embodiments.

FIGS. 2 through 24 illustrate cross-sectional views and top views of intermediate steps during a process for forming a package component in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an semiconductor package includes a front-side redistribution structure, a back-side redistribution structure, integrated circuit dies disposed between the front-side redistribution structure and the back-side redistribution structure, and through vias disposed besides the integrated circuit dies and connecting the front-side redistribution structure and the back-side redistribution structure. A backside enhancement layer is disposed on the back-side redistribution structure. For example, the semiconductor package may have an Integrated Fan-Out Bottom (InFO_B) structure. The InFO_B structure is different from the traditional Integrated Fan-Out Package-on-Package (InFO_PoP) structure because the InFO_B structure does not have a package mounted on top, and the users may mount any suitable device on a package with the InFO_B structure, which provides the users more flexibility in the applications of the package with the InFO_B structure.

In addition to the traditional contact pads in the back-side redistribution structure, such as power pads, ground pads, and signal pads, the package with the InFO_B structure may have a number of dummy pads as well to provide necessary mechanical support to a variety of devices that may be mounted on the package with the InFO_B structure according to the need of the users. Since the dummy pads are electrically isolated from the rest of the back-side redistribution structure, heat accumulation during the laser drilling process that reveals the dummy pads may cause delamination of the backside enhancement layer. Portions of the metallization patterns in the back-side redistribution structure may be used to form metal features with the dummy pads that may help to dissipate heat during the laser drilling process. Less heat accumulation on the dummy pads may help to reduce the likelihood of the delamination of the backside enhancement layer, thereby improving the long-term reliability of the semiconductor package. Less heat accumulation on the dummy pads may also help to reduce the oxidation of the contact pads, which may improve the wetting of the conductive materials on the contact pads during the formation of conductive connectors, thereby improving the quality of the conductive connectors formed.

Embodiments discussed herein are to provide examples to enable making and using the subject matter of this disclosure, and a person having ordinary skill in the art will readily understand modifications that can be made while remaining within contemplated scopes of different embodiments. Throughout the various views and illustrative embodiments, like reference numbers are used to designate like features. Although method embodiments may be discussed as being performed in a particular order, other method embodiments may be performed in any logical order.

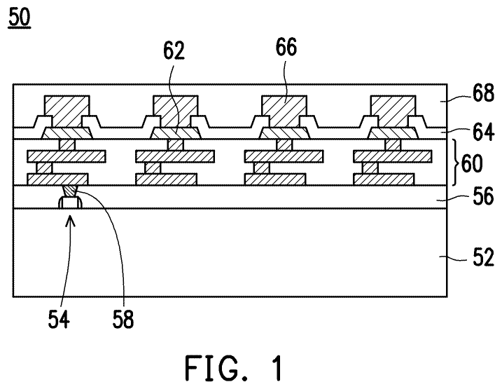

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), and sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

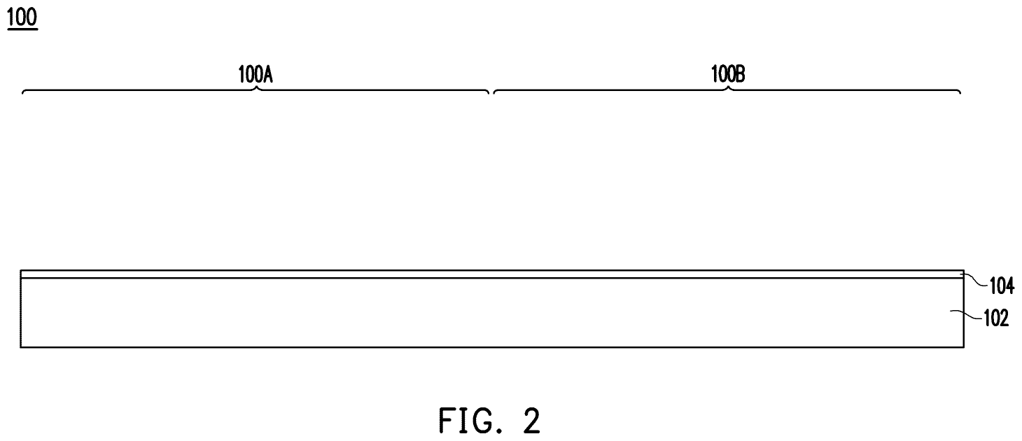

FIGS. 2 through 22 illustrate cross-sectional views and top views of intermediate steps during a process for forming a first package component 100, in accordance with some embodiments. A first package region 100A and a second package region 100B are illustrated, and one or more of the integrated circuit dies 50 are packaged to form an integrated circuit package in each of the package regions 100A and 100B. The integrated circuit packages may also be referred to as integrated fan-out (InFO) packages.

In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

A release layer 104 is formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

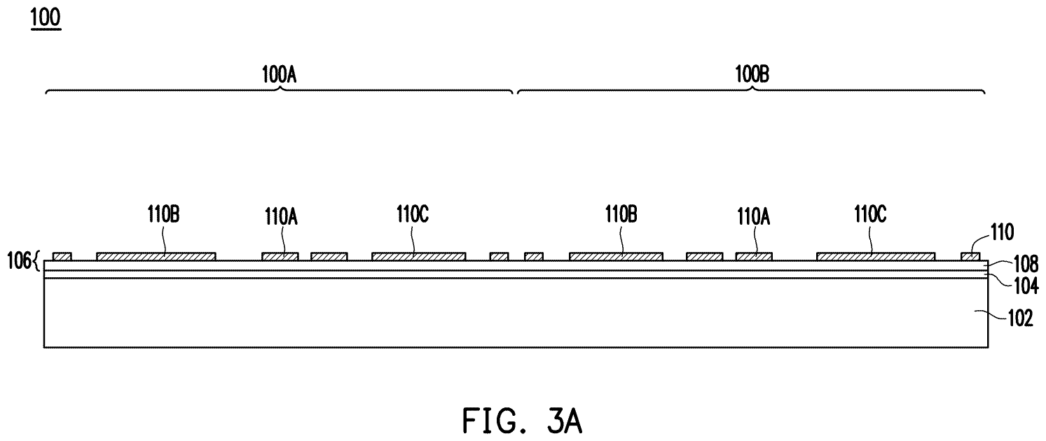

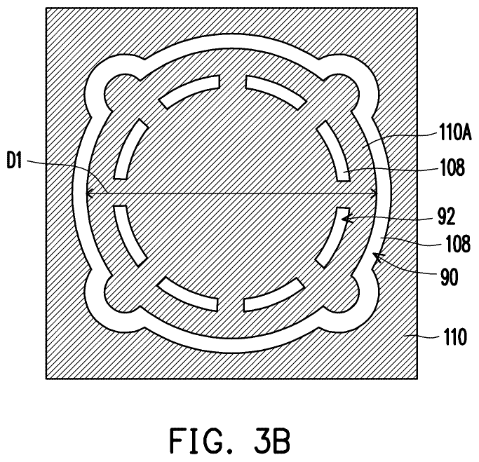

In FIGS. 3A through 6, a back-side redistribution structure 106 is formed on the release layer 104. As discussed in greater detail below, the back-side redistribution structure 106 is formed and through vias 116 are formed over the back-side redistribution structure 106. The back-side redistribution structure 106 may include one or more dielectric layers and metallization patterns (sometimes referred to as redistribution layers or redistribution lines).

In FIG. 3A, a dielectric layer 108 is formed on the release layer 104. The bottom surface of the dielectric layer 108 may be in contact with the top surface of the release layer 104. In some embodiments, the dielectric layer 108 is formed of a polymer, such as polybenzoxazole (PBO), polyimide, benzocyclobutene (BCB), or the like. In other embodiments, the dielectric layer 108 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 108 may be formed by any acceptable deposition process, such as spin coating, CVD, laminating, the like, or a combination thereof.

A metallization pattern 110 is formed on the dielectric layer 108. As an example to form metallization pattern 110, a seed layer is formed over the dielectric layer 108. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

Portions of the metallization pattern 110 may be used as contact pads in the first package component 100, which is discussed in greater detail below. The contact pads of the first package component 100 may comprise dummy pads 110A, power or ground pads 110B, and signal pads 110C. FIG. 3A shows one of each type of the contact pads in the first package region 10A and the second package region 10B, respectively, for illustrative purposes. In some embodiments, the first package region 100A or the second package region 100B may have other numbers of each type of the contact pads. For instance, a person of ordinary skill in the art will recognize that a circuit will generally include one (or more) of both a power pad and a ground pad, whereas solely for purposes of simplicity of illustration here, a single pad 110B, which represents both a power pad and a ground pad, is illustrated for each package region. FIG. 3B shows a top view of one dummy pad 110A, wherein the dummy pad 110A is isolated from the rest of the metallization pattern 110 by openings 90. The dummy pad 110A has a diameter D1 that may be about 360 μm, although other sizes are possible. The dummy pad 110A may have openings 92 that may reduce the stress on the surface of the dummy pad 110A. The dielectric layer 108 underneath the metallization pattern 110 are partially shown through the openings 90 and opening 92 in the top view.

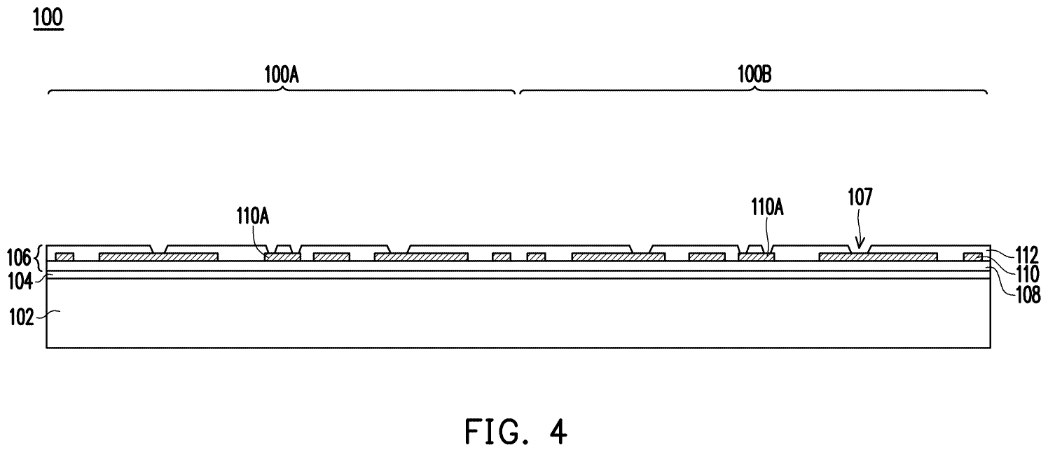

In FIG. 4, a dielectric layer 112 is formed on the metallization pattern 110 and the dielectric layer 108. The dielectric layer 112 may fill in the openings on the dummy pads 110A. In some embodiments, the dielectric layer 112 is formed of a polymer, which may be a photo-sensitive material such as PBO, polyimide, BCB, or the like, that may be patterned using a lithography mask. In other embodiments, the dielectric layer 112 is formed of a nitride such as silicon nitride; an oxide such as silicon oxide, PSG, BSG, BPSG; or the like. The dielectric layer 112 may be formed by spin coating, lamination, CVD, the like, or a combination thereof. The dielectric layer 112 is then patterned to form openings 107 exposing portions of the metallization pattern 110. The patterning may be formed by any acceptable process, such as by exposing the dielectric layer 112 to light when the dielectric layer 112 is a photo-sensitive material or by etching using, for example, an anisotropic etch. If the dielectric layer 112 is a photo-sensitive material, the dielectric layer 112 can be developed after the exposure.

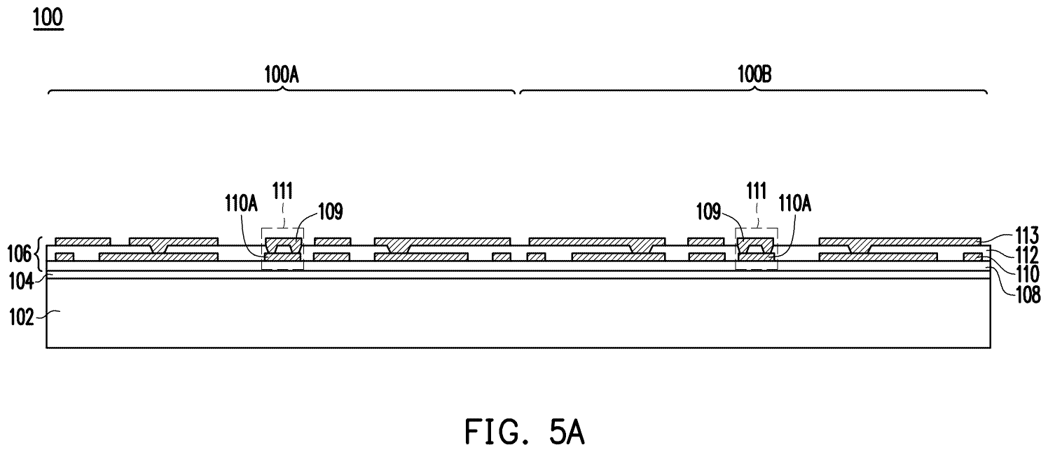

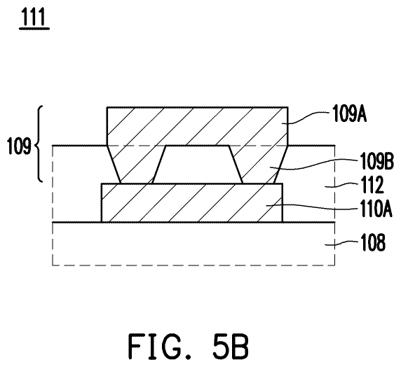

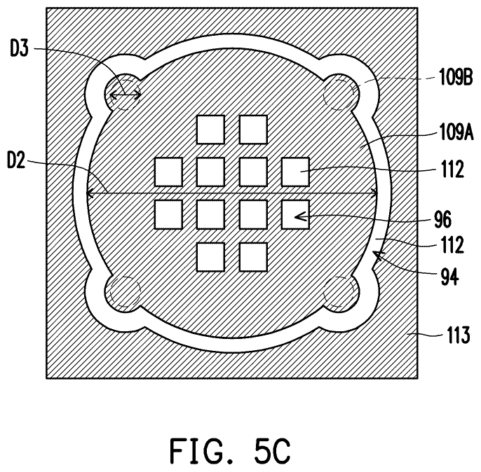

In FIG. 5A, metallization pattern 113 is formed on the dielectric layer 112. The metallization pattern 113 includes portions on and extending along a major surface of the dielectric layer 112. The metallization pattern 113 further includes portions extending through the dielectric layer 112 to physically and electrically couple to the metallization pattern 110. The metallization pattern 113 may be formed in a similar manner and of a similar material as the metallization pattern 110. As show in FIG. 5A, the portions of the metallization pattern 113 that are physically and electrically coupled to the dummy pads 110A are collectively referred to as metallization patterns 109. One dummy pad 110A and one metallization pattern 109 are collectively referred to as metal feature 111, which may function as a heat dissipation system as discussed in great detail below. FIG. 5B shows the metal feature 111 in greater detail, which includes a metal pad 109A, metal vias 109B, and the dummy pad 110A. The metal pad 109A and the metal vias 109B make up the metallization pattern 109. FIG. 5C, shows a top view of the metallization pattern 109, wherein the metallization pattern 109 is isolated from the rest of the metallization pattern 113 by openings 94. The metal pad 109A has a diameter D2 that may be about 350 μm, although other sizes are possible. The metal pad 109A may have openings 96 that may reduce the stress on the surface of the metal pad 109A. The dielectric layer 112 underneath the metallization pattern 113 are partially shown through the openings 94 and opening 96 in the top view. The metal vias 109B may not be visible in the top view, but are shown in dashed outlines for illustrative purposes. FIG. 5C shows four metal vias 109B underneath the metal pad 109A for illustrative purposes. In some embodiments, other numbers of metal vias 109B may be disposed beneath the metal pad 109A, such one via, two vias, three vias, or more. The metal vias 109B has a diameter D3 that may be in a range from 20 μm to about 35 μm, such as about 20 μm.

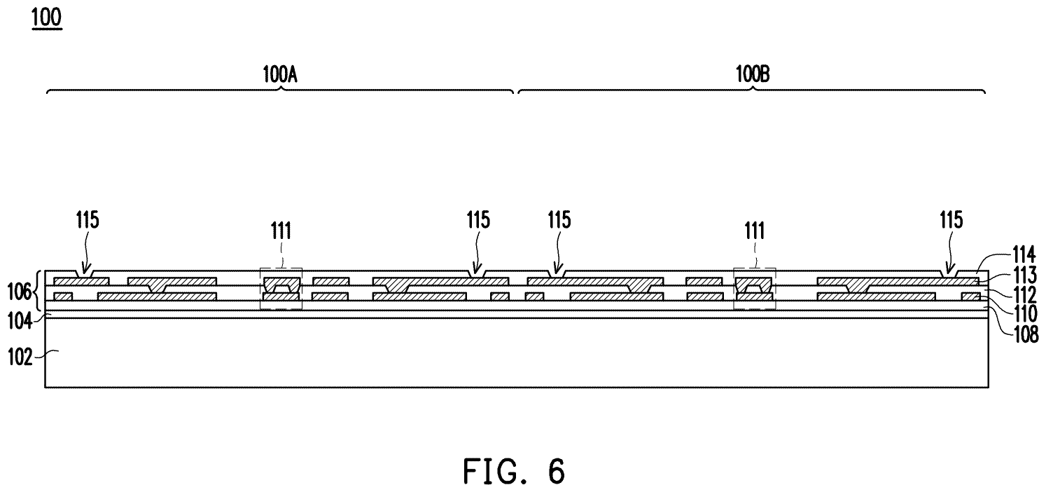

In FIGS. 6, a dielectric layer 114 is deposited on the metallization pattern 113 and the dielectric layer 112. The dielectric layer 114 may fill in the openings on the metal pads 109A. The dielectric layer 114 may be formed in a manner similar to the dielectric layer 112, and may be formed of a similar material as the dielectric layer 112. The dielectric layer 114 is then patterned to form openings 115 exposing portions of the metallization pattern 113. The patterning may be formed by an acceptable process, such as by exposing the dielectric layer 114 to light when the dielectric layer 114 is a photo-sensitive material or by etching using, for example, an anisotropic etch. If the dielectric layer 114 is a photo-sensitive material, the dielectric layer 114 can be developed after the exposure.

FIG. 6 illustrates a back-side redistribution structure 106 having two metallization patterns, which are the metallization pattern 110 and the metallization pattern 113, for illustrative purposes. In some embodiments, the back-side redistribution structure 106 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

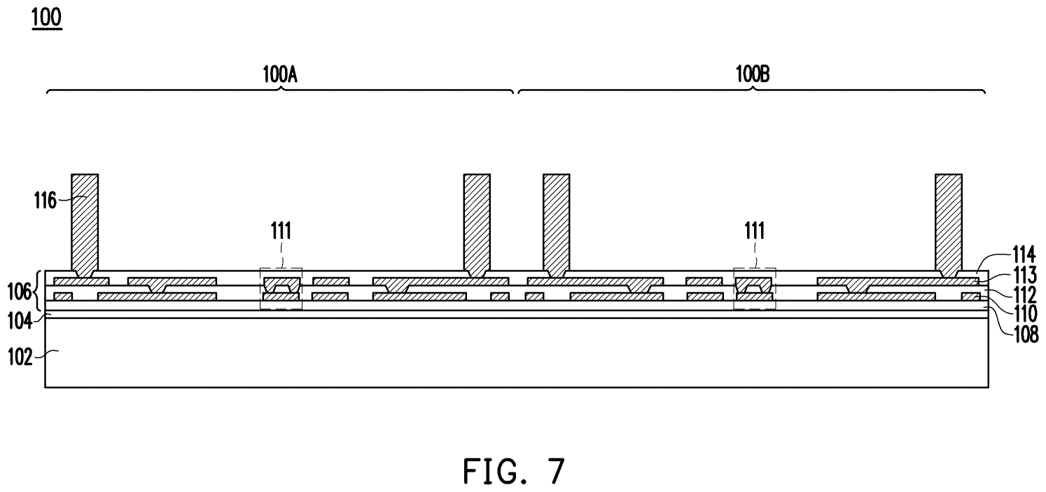

In FIG. 7, through vias 116 are formed in the openings 115 and extending away from the topmost dielectric layer of the back-side redistribution structure 106 (e.g., the dielectric layer 114). As an example to form the through vias 116, a seed layer (not shown) is formed over the back-side redistribution structure 106, e.g., on the dielectric layer 114 and portions of the metallization pattern 113 exposed by the openings 115. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 116.

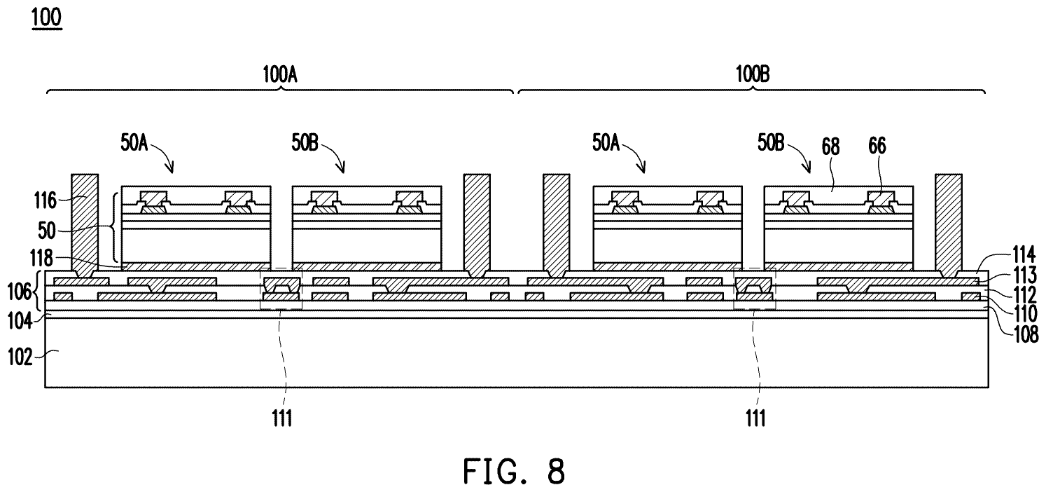

In FIG. 8, integrated circuit dies 50 (e.g., a first integrated circuit die 50A and a second integrated circuit die 50B) are adhered to the dielectric layer 114 by an adhesive 118, although other bonding techniques such as thermal bonding, thermal compression, and the like, are contemplated herein. A desired type and quantity of integrated circuit dies 50 are adhered in each of the package regions 100A and 100B. In the embodiment shown, multiple integrated circuit dies 50 are adhered adjacent one another, including the first integrated circuit die 50A and the second integrated circuit die 50B in each of the first package region 100A and the second package region 100B. The first integrated circuit die 50A may be a logic device, such as a central processing unit (CPU), a graphics processing unit (GPU), a system-on-a-chip (SoC), a microcontroller, or the like. The second integrated circuit die 50B may be a memory device, such as a dynamic random access memory (DRAM) die, a static random access memory (SRAM) die, a hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). The space available for the through vias 116 in the first package region 100A and the second package region 100B may be limited, particularly when the integrated circuit dies 50 include devices with a large footprint, such as SoCs. Use of the back-side redistribution structure 106 allows for an improved interconnect arrangement when the first package region 100A and the second package region 100B have limited space available for the through vias 116.

The adhesive 118 is on back-sides of the integrated circuit dies 50 and adheres the integrated circuit dies 50 to the back-side redistribution structure 106, such as to the dielectric layer 114. The adhesive 118 may be any suitable adhesive, epoxy, die attach film (DAF), or the like. The adhesive 118 may be applied to back-sides of the integrated circuit dies 50 or may be applied to an upper surface of the back-side redistribution structure 106 if applicable. For example, the adhesive 118 may be applied to the back-sides of the integrated circuit dies 50 before singulating to separate the integrated circuit dies 50.

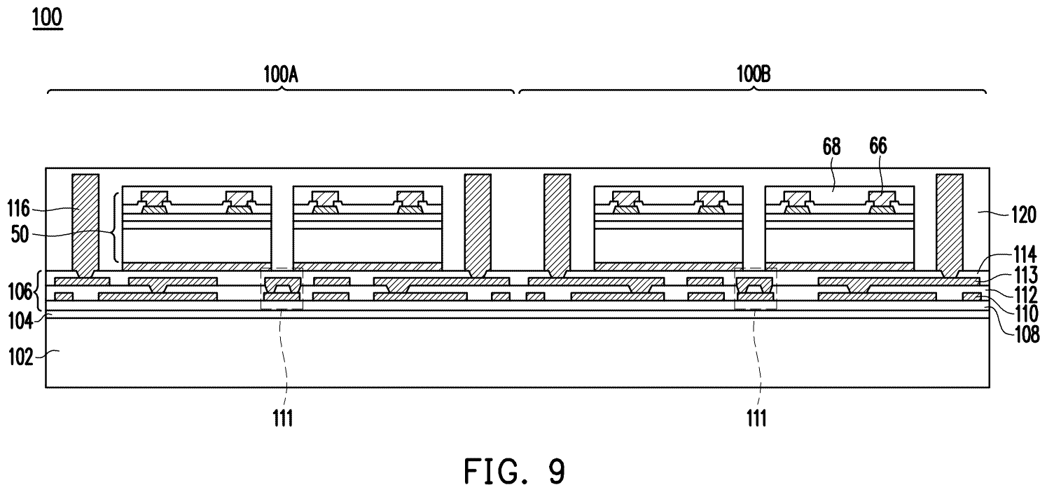

In FIG. 9, an encapsulant 120 is formed on and around the various components. After formation, the encapsulant 120 encapsulates the through vias 116 and integrated circuit dies 50. The encapsulant 120 may be a molding compound, epoxy, or the like. The encapsulant 120 may be applied by compression molding, transfer molding, or the like, and may be formed over the carrier substrate 102 such that the through vias 116 and/or the integrated circuit dies 50 are buried or covered. The encapsulant 120 is further formed in gap regions between the integrated circuit dies 50. The encapsulant 120 may be applied in liquid or semi-liquid form and then subsequently cured.

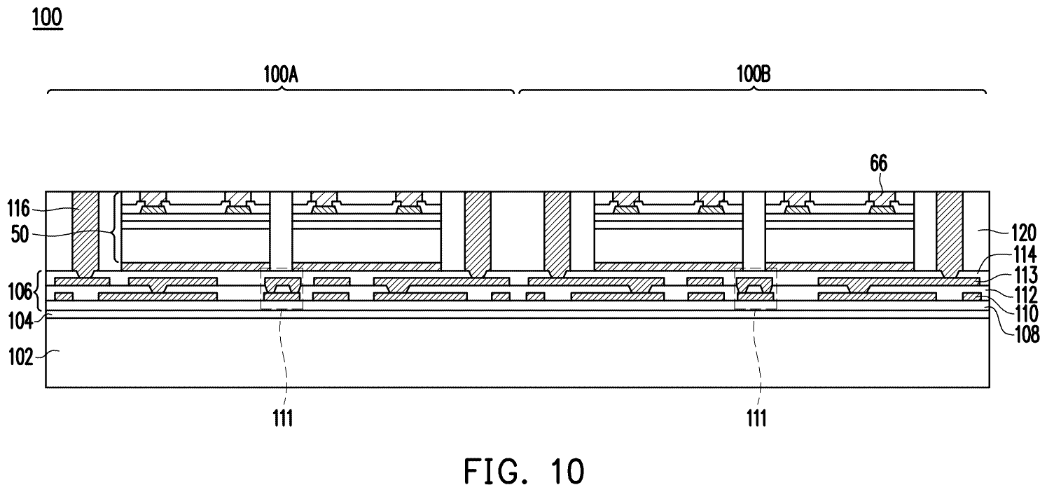

In FIG. 10, a planarization process is performed on the encapsulant 120 to expose the through vias 116 and the die connectors 66. The planarization process may also remove material of the through vias 116, dielectric layer 68, and/or die connectors 66 until the die connectors 66 and through vias 116 are exposed. Top surfaces of the through vias 116, die connectors 66, dielectric layer 68, and encapsulant 120 are substantially coplanar after the planarization process within process variations. The planarization process may be, for example, a chemical-mechanical polish (CMP), a grinding process, or the like. In some embodiments, the planarization may be omitted, for example, if the through vias 116 and/or die connectors 66 are already exposed.

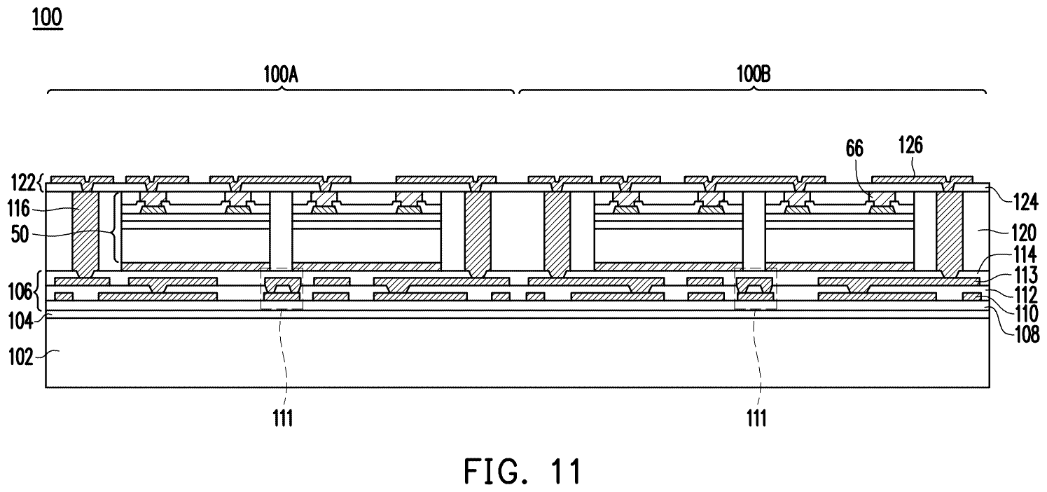

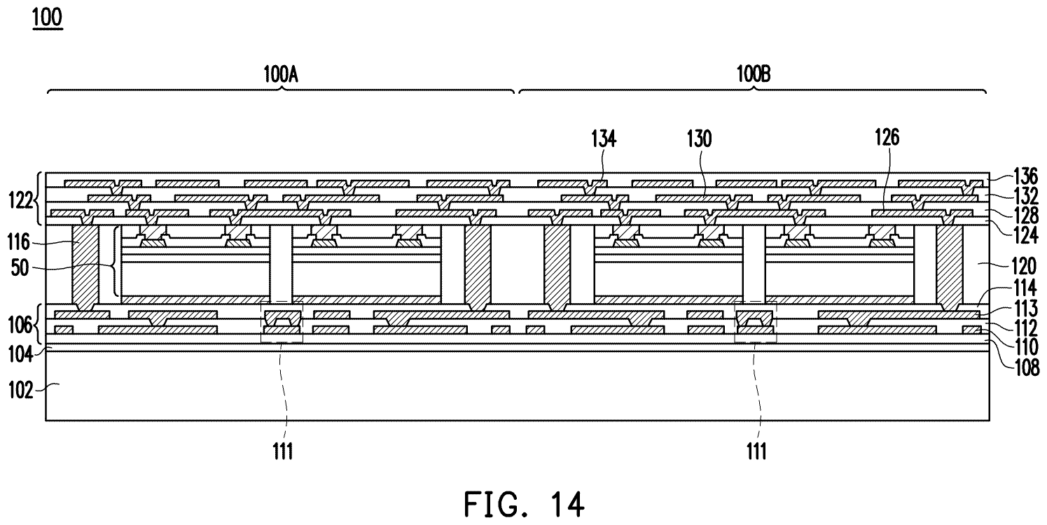

In FIGS. 11 through 14, a front-side redistribution structure 122 (see FIG. 14) is formed over the encapsulant 120, through vias 116, and integrated circuit dies 50. The front-side redistribution structure 122 includes dielectric layers 124, 128, 132, and 136; and metallization patterns 126, 130, and 134. The metallization patterns may also be referred to as redistribution layers or redistribution lines. The front-side redistribution structure 122 is shown as an example having three layers of metallization patterns. More or fewer dielectric layers and metallization patterns may be formed in the front-side redistribution structure 122. If fewer dielectric layers and metallization patterns are to be formed, steps and process discussed below may be omitted. If more dielectric layers and metallization patterns are to be formed, steps and processes discussed below may be repeated.

In FIG. 11, the dielectric layer 124 is deposited on the encapsulant 120, through vias 116, and die connectors 66. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the through vias 116 and the die connectors 66. The patterning may be by an acceptable process, such as by exposing and developing the dielectric layer 124 to light when the dielectric layer 124 is a photo-sensitive material or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically couple to the through vias 116 and the integrated circuit dies 50. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

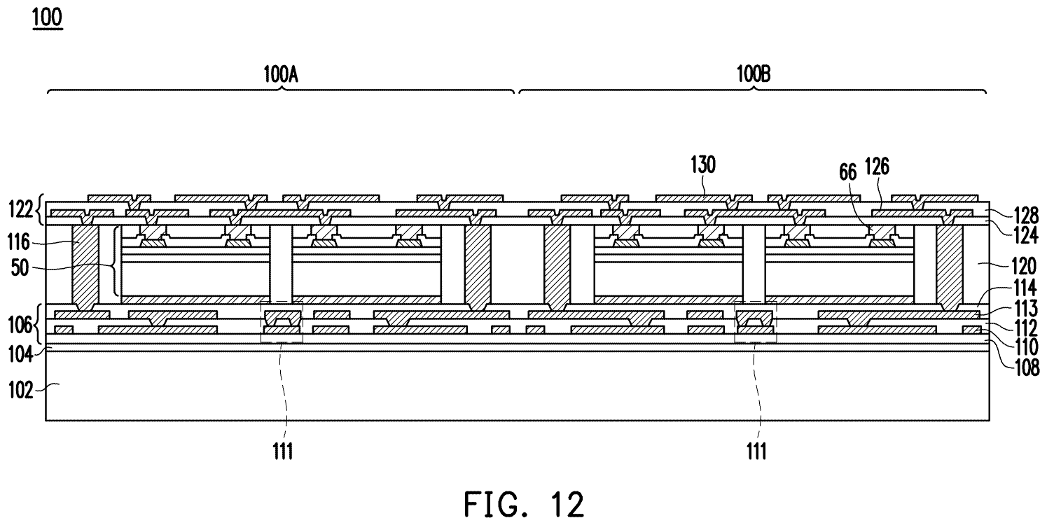

In FIG. 12, the dielectric layer 128 is deposited on the metallization pattern 126 and the dielectric layer 124. The dielectric layer 128 may be formed in a manner similar to the dielectric layer 124, and may be formed of a similar material as the dielectric layer 124.

The metallization pattern 130 is then formed. The metallization pattern 130 includes portions on and extending along the major surface of the dielectric layer 128. The metallization pattern 130 further includes portions extending through the dielectric layer 128 to physically and electrically couple the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126.

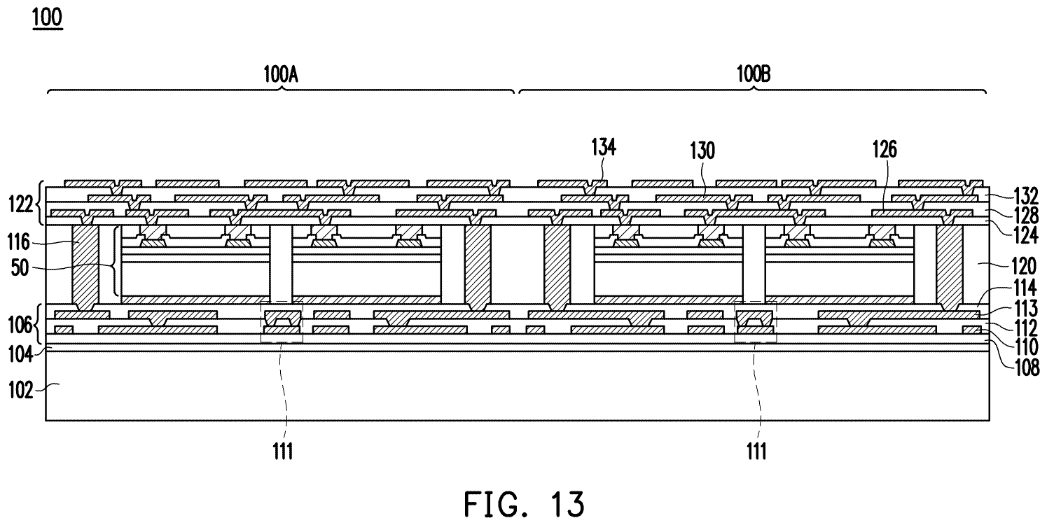

In FIG. 13, the dielectric layer 132 is deposited on the metallization pattern 130 and the dielectric layer 128. The dielectric layer 132 may be formed in a manner similar to the dielectric layer 124, and may be formed of a similar material as the dielectric layer 124.

The metallization pattern 134 is then formed. The metallization pattern 134 includes portions on and extending along the major surface of the dielectric layer 132. The metallization pattern 134 further includes portions extending through the dielectric layer 132 to physically and electrically couple the metallization pattern 130. The metallization pattern 134 may be formed in a similar manner and of a similar material as the metallization pattern 126. The metallization pattern 134 is the topmost metallization pattern of the front-side redistribution structure 122. As such, all of the intermediate metallization patterns of the front-side redistribution structure 122 (e.g., the metallization patterns 126 and 130) are disposed between the metallization pattern 134 and the integrated circuit dies 50. In some embodiments, the metallization pattern 134 has a different size than the metallization patterns 126 and 130. For example, the conductive lines and/or vias of the metallization pattern 134 may be wider or thicker than the conductive lines and/or vias of the metallization patterns 126 and 130. Further, the metallization pattern 134 may be formed to a greater pitch than the metallization pattern 130.

In FIG. 14, the dielectric layer 136 is deposited on the metallization pattern 134 and the dielectric layer 132. The dielectric layer 136 may be formed in a manner similar to the dielectric layer 124, and may be formed of the same material as the dielectric layer 124. The dielectric layer 136 is the topmost dielectric layer of the front-side redistribution structure 122. As such, all of the metallization patterns of the front-side redistribution structure 122 (e.g., the metallization patterns 126, 130, and 134) are disposed between the dielectric layer 136 and the integrated circuit dies 50. Further, all of the intermediate dielectric layers of the front-side redistribution structure 122 (e.g., the dielectric layers 124, 128, 132) are disposed between the dielectric layer 136 and the integrated circuit dies 50.

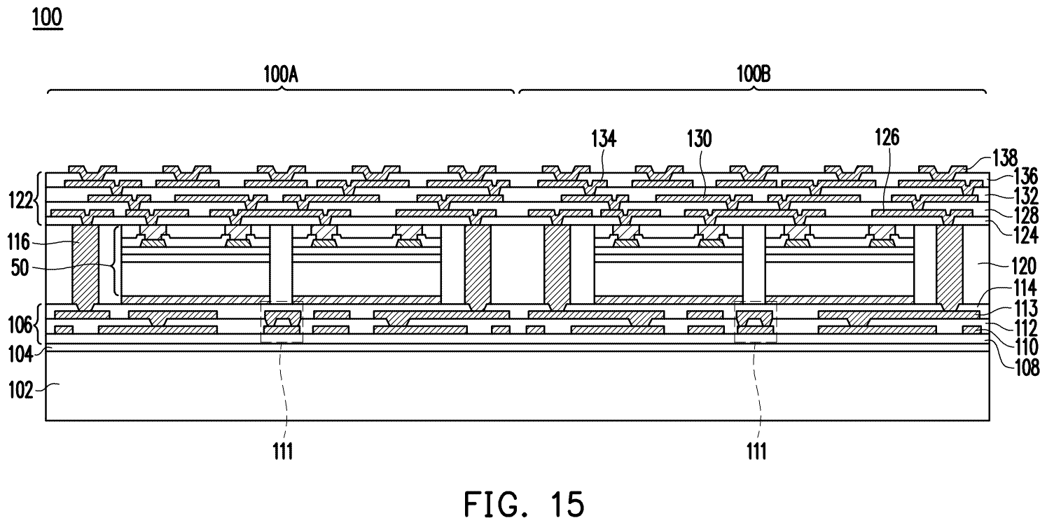

In FIG. 15, under-bump metallurgies (UBMs) 138 are formed for external connection to the front-side redistribution structure 122. The UBMs 138 have bump portions on and extending along the major surface of the dielectric layer 136, and have via portions extending through the dielectric layer 136 to physically and electrically couple to the metallization pattern 134. As a result, the UBMs 138 are electrically coupled to the through vias 116 and the integrated circuit dies 50. The UBMs 138 may be formed of the same material as the metallization pattern 126. In some embodiments, the UBMs 138 have a different size than the metallization patterns 126, 130, and 134.

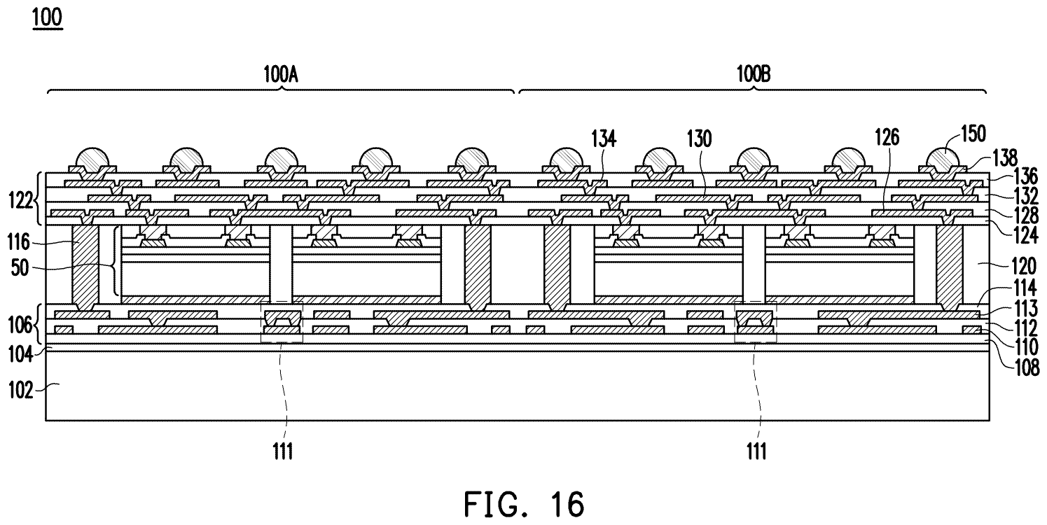

In FIG. 16, conductive connectors 150 are formed on the UBMs 138. The conductive connectors 150 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 150 may include a conductive material such as solder, copper, aluminum, gold, nickel, silver, palladium, tin, the like, or a combination thereof. In some embodiments, the conductive connectors 150 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 150 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

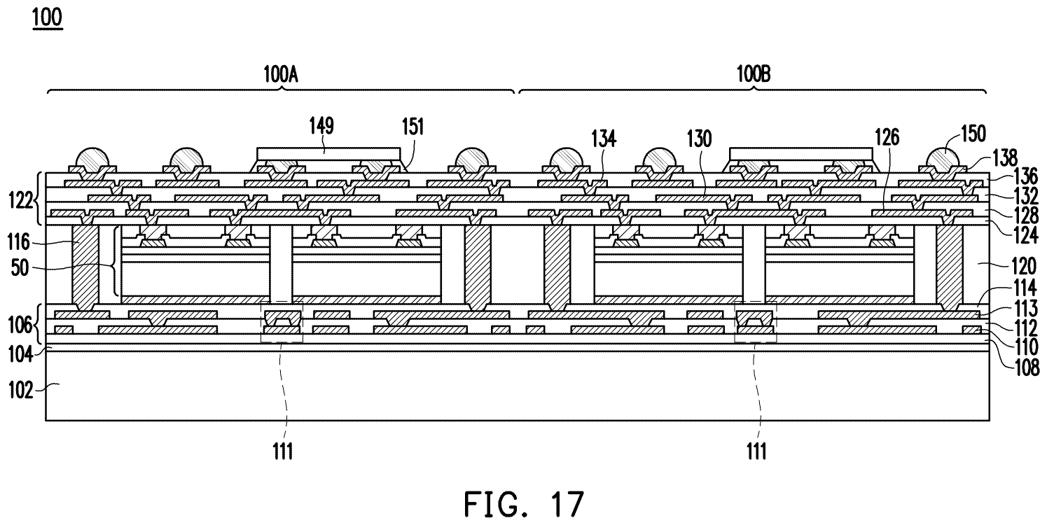

In FIG. 17, integrated passive devices (IPDs) 149 are bonded to the front-side redistribution structure 122 through some of the conductive connectors 150. The IPDs 149 may be or may comprise a passive device such as a capacitor die, an inductor die, a resistor die, or the like, or may include the combinations of the passive devices. An underfill 151 is formed between the IPDs 149 and the dielectric layer 136, surrounding some of the conductive connectors 150. The underfill may reduce stress and protect the joints resulting from the reflowing of the conductive connectors 150. The underfill may be formed by a capillary flow process after the IPD 149s are attached, or may be formed by a suitable deposition method before the IPD 149s are attached.

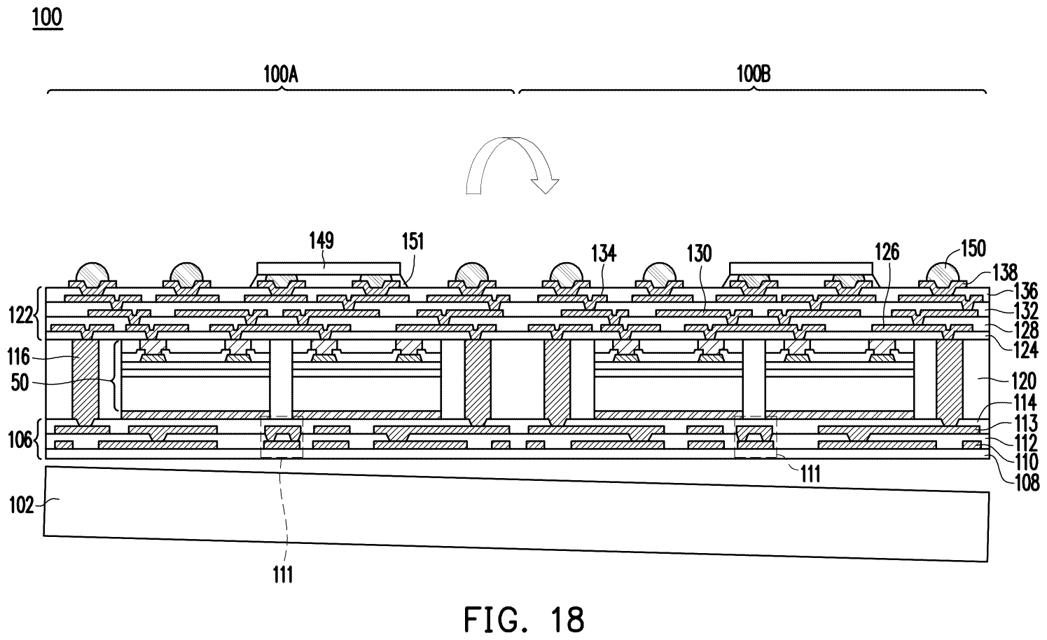

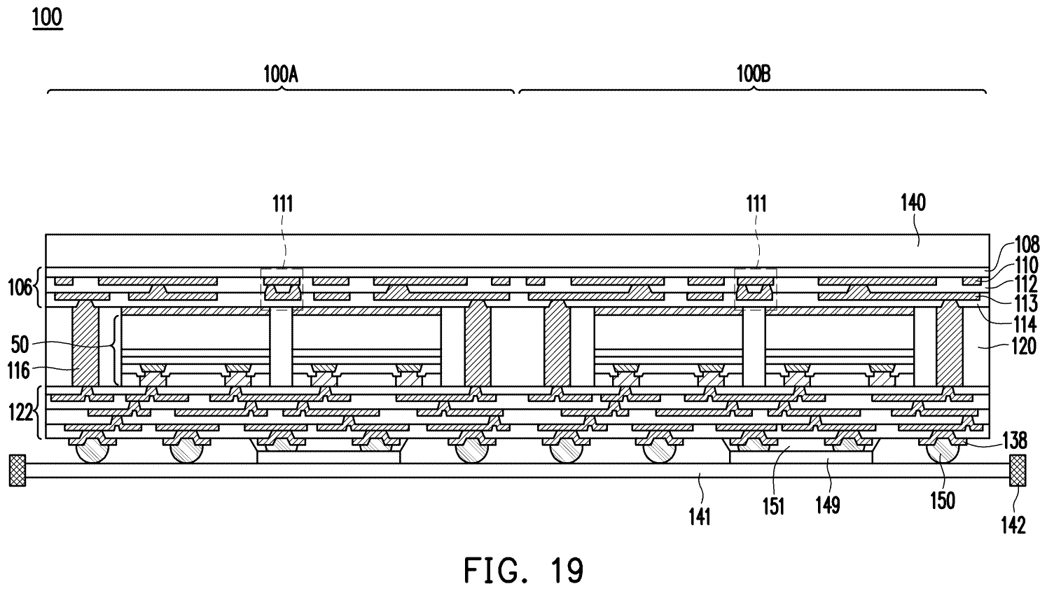

In FIG. 18, a carrier substrate de-bonding is performed to detach (or de-bond) the carrier substrate 102 from the back-side redistribution structure 106, e.g., the dielectric layer 108. In accordance with some embodiments, the de-bonding includes projecting a light, such as a laser light or an UV light on the release layer 104 (not shown), so that the release layer 104 decomposes under the heat of the light and the carrier substrate 102 can be removed. The structure may be flipped over and placed on tape 141, which is supported by frame 142 (shown in FIG. 19).

In FIG. 19, a back-side enhancement layer (BEL) 140 is formed over the back-side redistribution structure 106 to reduce warpage of the back-side redistribution structure 106 during later manufacturing steps. The BEL 140 may be comprise a molding compound, such as a polymer, an epoxy, silicon oxide filler material, the like, or a combination thereof. The BEL 140 may be formed by compression molding, transfer molding, or the like. A curing process may be performed to cure the BEL 140 and the curing process may be a thermal curing, a UV curing, the like, or a combination thereof. The BEL 140 may have a substantial degree of transparency. The BEL 140 may have a thickness in a range of about 25 μm to about 50 μm, such as about 50 μm.

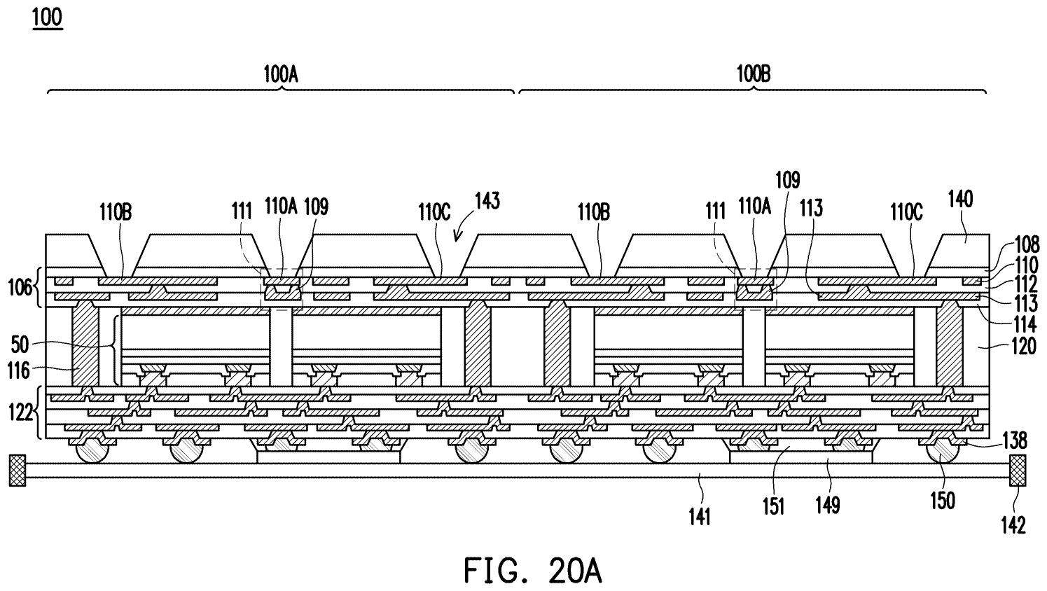

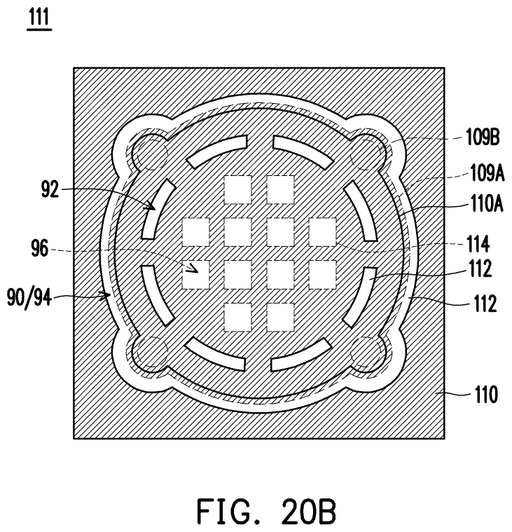

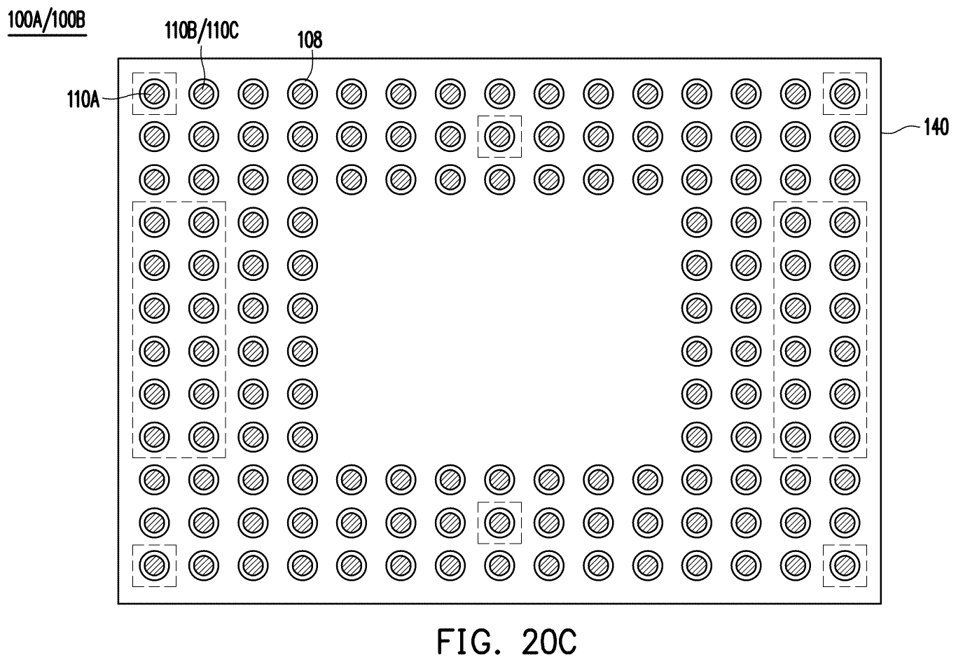

In FIG. 20A, openings 143 are formed through the BEL 140 and the dielectric layer 108 to expose the contact pads of the first package component 100, which may comprise the dummy pads 110A, the power or ground pads 110B, and the signal pads 110C. The dummy pads 110A may provide mechanical support to any devices that may be mounted on the first package component 100 and have no electrical functionality. The power pads 110B provide electrical connections points between an external power source and the first package component 100. The ground pads 110B provide electrical connections points between the electrical ground and the first package component 100. The signal pads 110C provide communication pathways between any devices that may be mounted on the first package component 100 and the first package component 100. The openings 143 may be formed, for example, using laser drilling, etching, or the like. In some embodiments, the metallization patterns 109 of the metal features 111 help to dissipate heat that may be accumulated in the dummy pads 110A during the laser drilling process, which reduces the likelihood of the delamination of the BEL 140, thereby improving the long-term reliability of the first package component 100.

In FIG. 20B, a top view of the metal feature 11 is shown. The metal pad 109A, the metal vias 109B, the openings 96 and the dielectric layer 114 may not be visible in the top view, but are shown in dashed outlines for illustrative purposes. The dummy pad 110A is isolated from the rest of the metallization pattern 110 by openings 90, and the metal pad 109A is isolated from the rest of the metallization pattern 113 by openings 94 (shown in FIG. 20A). Openings 90 and opening 94 overlap with each other in the top view shown in FIG. 20B. The metal vias 109B connect the dummy pad 110A to the metal pad 109A to form the metal feature 111, which is electrically isolated from the rest of the back-side redistribution structure 106 (shown in FIG. 20A). In other words, the metal feature 111 is electrically isolated from circuits of the first package component 100. The openings 92 of the dummy pad 110A are filled with the dielectric layer 112 and the openings 96 of the metal pad 109A are filled with the dielectric layer 114. FIG. 20B shows the metal pad 109A as larger than the dummy pad 110A for illustrative purposes. In some embodiments, the size of the metal pad 109A may be smaller than or equal to the size of the dummy pad 110A. FIG. 20B shows the metal pad 109A disposed directly beneath the dummy pad 110A for illustrative purposes. The metal pad 109A may be at any location beneath the dummy pad 110A. While four metal vias 109B are shown in this embodiment, a person of ordinary skill in the art will recognize that the number, size, and placement of the vias can be modified and optimized to provide sufficient heat dissipation through routine experimentation.

FIG. 20C shows a top view of the first package region 100A or the second package region 100B in accordance with some embodiments. Dummy pads 110A, power or ground pads 110B, and signal pads 110C may be disposed in an array comprising columns and rows on the first package region 100A or the second package region 100B, wherein the array may have a center region free of any metallization pattern 110. Portions of the metallization pattern 110 encircled by dashed lines may be the dummy pads 110A and the other portions of the metallization pattern 110 shown may be the power or ground pads 110B or the signal pads 110C. Each dummy pad 110A, power or ground pad 110B, and signal pad 110C may be encircled by the dielectric layer 108 in the top view. As shown in FIG. 20C, the dummy pads 110A may be disposed at corners of the first package region 100A or the second package region 100B, and the dummy pads 110A may be disposed along opposing edges of the first package region 100A or the second package region 100B.

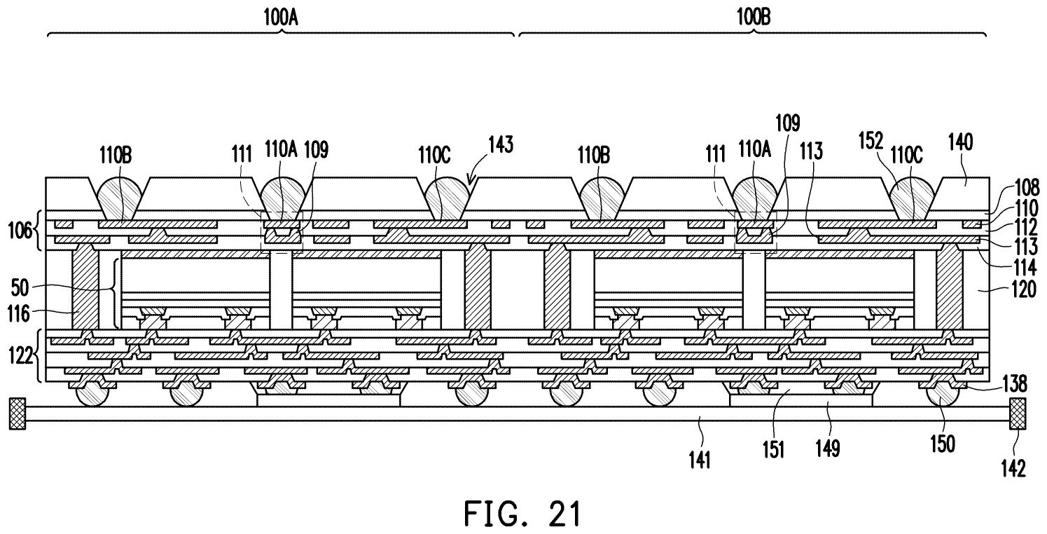

In FIG. 21, conductive connectors 152 are formed extending through the BEL 140 and the dielectric layer 108 to contact the dummy pads 110A, the power or ground pads 110B, and the signal pads 110C, respectively. The conductive connectors 152 may be formed of conductive materials in the openings 143. In some embodiments, the conductive connectors 152 comprise flux and are formed in a flux dipping process. In some embodiments, the conductive connectors 152 comprise a conductive paste such as solder paste, silver paste, or the like, and are dispensed in a printing process. In some embodiments, the conductive connectors 152 are formed in a manner similar to the conductive connectors 150, and may be formed of a similar material as the conductive connectors 150. As discussed above, the metallization patterns 109 of the metal features 111 may help to reduce heat accumulation in the dummy pads 110A during the laser drilling process. Less heat accumulation in the dummy pads 110A reduces the oxidation of the dummy pads 110A, which improves the wetting of the conductive materials on the dummy pads 110A during the formation of the conductive connectors 152, thereby improving the quality of the conductive connectors 152 formed.

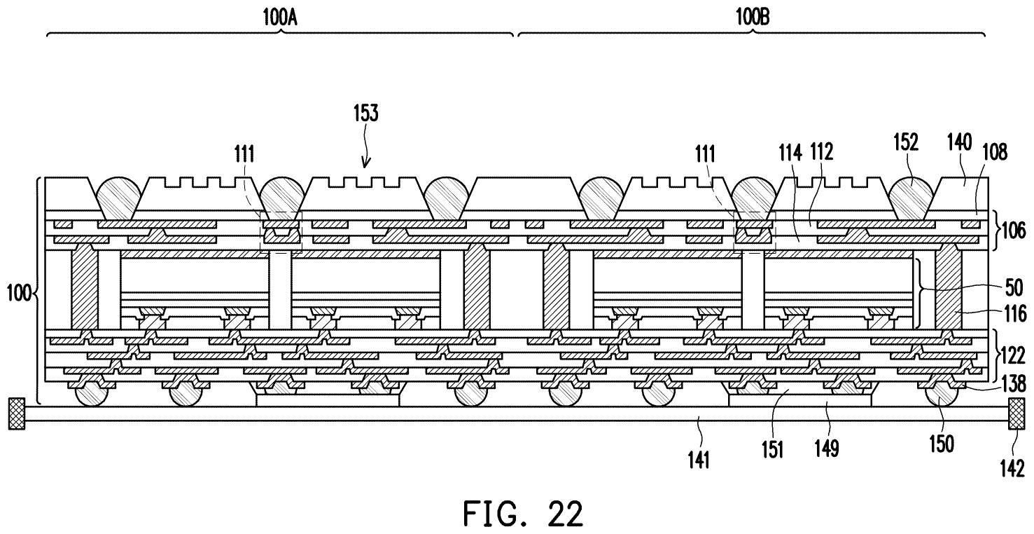

In FIG. 22, marks 153 are formed on the portions of the BEL 140 that are over the integrated circuit dies 50. The marks 153 may display information regarding the corresponding integrated circuit dies 50 disposed underneath. The marks 153 may be formed by laser marking or any similar marking technique. All features shown in FIG. 22 may be collectively referred to as the first package component 100.

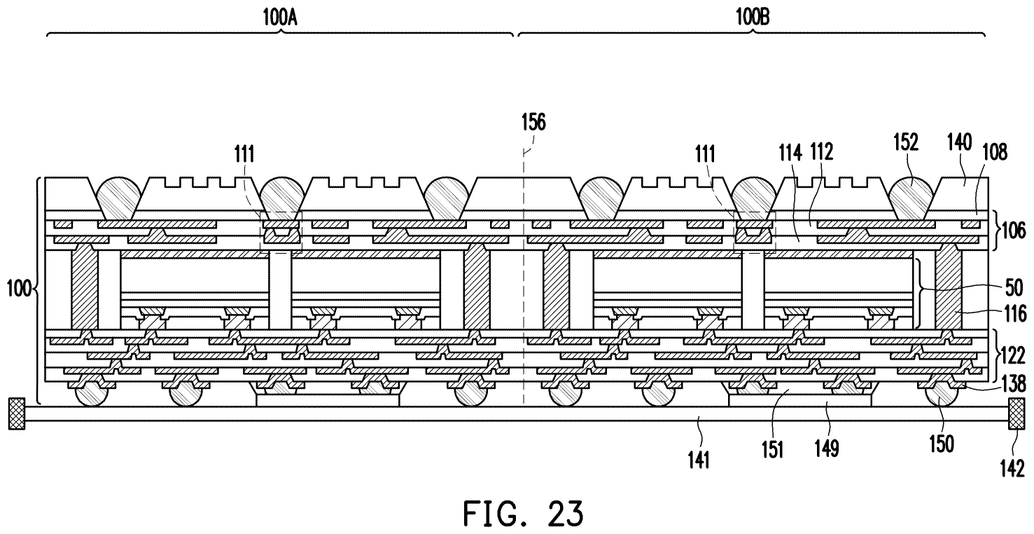

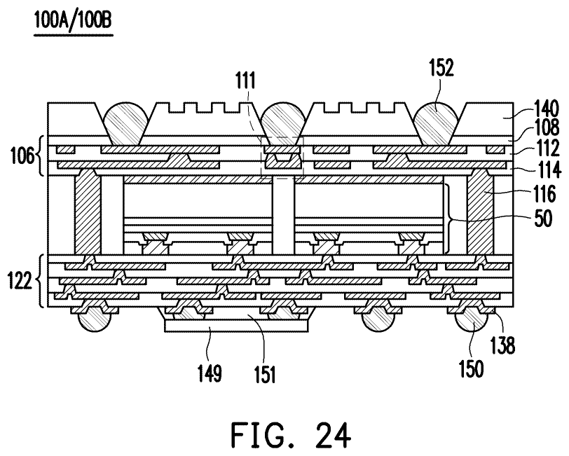

In FIG. 23, the first package component 100 is singulated along scribe line 156, so that the first package component 100 is separated into discrete integrated circuit packages, which are removed from tape 141 after singulation. After singulation, the first package region 100A may be referred to as first package 100A and the second package region 100B may be referred to as second package 100B. FIG. 24 shows a discrete integrated circuit package, which may be the first package 100A or the second package 100B.

The embodiments of the present disclosure have some advantageous features. By forming the metal feature 111, the heat generated during the laser drilling process on the BEL140 and the back-side redistribution structure 106 is dissipated more efficiently on the dummy pads 110A. Less heat accumulation on the dummy pads 110A may help to reduce the likelihood of delamination of the BEL 140, thereby improving the long-term reliability of the first package 100A and the second package 100B. Less heat accumulation on the dummy pads 110A may also help to reduce the oxidation of the dummy pads 110A, which may improve the wetting of the conductive materials on the dummy pads 110A during the formation of conductive connectors 152, thereby improving the quality of the conductive connectors 152 formed.

In an embodiment, a semiconductor includes a redistribution structure, the redistribution structure including: a first dielectric layer; a first metal pattern in the first dielectric layer, wherein a first portion of the first metal pattern is a metal pad; a second dielectric layer over the first metal pattern; and a second metal pattern in the second dielectric layer, wherein a first portion of the second metal pattern is a dummy pad, wherein the first portion of the first metal pattern is connected to the first portion of the second metal pattern by one or more metal vias extending through the second dielectric layer, and wherein the first portion of the first metal pattern, the first portion of the second metal pattern, and the one or more metal vias are electrically isolated from remaining portions of the redistribution structure; and a third dielectric layer over the second metal pattern. In an embodiment, the metal pad have openings that extend through a thickness of the metal pad. In an embodiment, the openings are filled in by the first dielectric layer. In an embodiment, the dummy pad have openings that extend through a thickness of the dummy pad. In an embodiment, the openings are filled in by the second dielectric layer. In an embodiment, the second metal pattern also includes a power pad, a ground pad, and a signal pad. In an embodiment, the semiconductor package further includes an insulating layer over the third dielectric layer and an electrical connector extending through the insulating layer and the third dielectric layer to contact the first portion of the second metal pattern. In an embodiment, the insulating layer includes a molding compound.

In an embodiment, a semiconductor package includes a redistribution structure including: a first insulating layer; a first redistribution pattern in the first insulating layer; a second insulating layer over the first redistribution pattern; and a second redistribution pattern in the second insulating layer, wherein the second redistribution pattern includes a plurality of contact pads including: signal pads; power pads; ground pads; and dummy pads; wherein first portions of the first redistribution pattern are connected to the dummy pads by vias extending through the second insulating layer; a heat dissipation system including: the first portions of the first redistribution pattern; the dummy pads; and the vias, wherein the heat dissipation system is electrically isolated from circuits of the semiconductor package; and a third insulating layer over the second redistribution pattern. In an embodiment, the plurality of contact pads are disposed on the semiconductor package in an array including columns and rows in a top view, and wherein a center region of the array is free of contact pads. In an embodiment, the plurality of contact pads are disposed on the semiconductor package in an array including columns and rows in a top view, and wherein one or more dummy pads are disposed in a column closest to an edge of the semiconductor package. In an embodiment, the dummy pads have openings that extend from top surfaces of the dummy pads to bottom surfaces of the dummy pads. In an embodiment, the semiconductor package further includes a fourth insulating layer over the third insulating layer and contact pad connectors extending through the third insulating layer and fourth insulating layer to contact the plurality of contact pads, wherein the fourth insulating layer includes an epoxy.

In an embodiment, a method of manufacturing a semiconductor package includes depositing a first dielectric layer over a carrier substrate; forming a first redistribution pattern on a first side of the first dielectric layer, wherein first portions of the first redistribution pattern are electrically isolated from remaining portions of the first redistribution pattern; depositing a second dielectric layer on the first redistribution pattern and the first dielectric layer; forming openings in the second dielectric layer to partially expose the first portions of the first redistribution pattern; forming a second redistribution pattern on the second dielectric layer, wherein the second redistribution pattern fills in the openings in the second dielectric layer and forms vias, wherein first portions of the second redistribution pattern are electrically isolated from remaining portions of the second redistribution pattern, and wherein the vias connect the first portions of the first redistribution pattern to the first portions of the second redistribution pattern; and depositing a third dielectric layer on the second redistribution pattern and the second dielectric layer. In an embodiment, the first portions of the first redistribution pattern are disposed at corners of the semiconductor package in a top view. In an embodiment, the first portions of the first redistribution pattern are disposed along opposing edges of the semiconductor package in a top view. In an embodiment, the method further includes depositing an insulating layer on a second side of the first dielectric layer, wherein the insulating layer includes a molding compound. In an embodiment, the method further includes creating openings through the insulating layer and the first dielectric layer by a laser drilling process to expose the first portions of the first redistribution pattern, wherein the vias and the first portions of the second redistribution pattern dissipate heat accumulated on the first portions of the first redistribution pattern during the laser drilling process. In an embodiment, the first portions of the first redistribution pattern have openings and wherein the openings are filled in by the second dielectric layer. In an embodiment, the first portions of the second redistribution pattern have openings and wherein the openings are filled in by the third dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor package, the method comprising:
depositing a first dielectric layer over a carrier substrate;
forming a first redistribution pattern on a first side of the first dielectric layer, wherein first portions of the first redistribution pattern are electrically isolated from remaining portions of the first redistribution pattern;
depositing a second dielectric layer on the first redistribution pattern and the first dielectric layer;
forming openings in the second dielectric layer to partially expose the first portions of the first redistribution pattern;
forming a second redistribution pattern on the second dielectric layer, wherein the second redistribution pattern fills in the openings in the second dielectric layer and forms vias, wherein first portions of the second redistribution pattern are electrically isolated from remaining portions of the second redistribution pattern, and wherein the vias connect the first portions of the first redistribution pattern to the first portions of the second redistribution pattern; and
depositing a third dielectric layer on the second redistribution pattern and the second dielectric layer.

2. The method of claim 1, wherein the first portions of the first redistribution pattern are disposed at corners of the semiconductor package in a top view.

3. The method of claim 1, wherein the first portions of the first redistribution pattern are disposed along opposing edges of the semiconductor package in a top view.

4. The method of claim 1, further comprising depositing an insulating layer on a second side of the first dielectric layer, wherein the insulating layer comprises a molding compound.

5. The method of claim 4, further comprising creating openings through the insulating layer and the first dielectric layer by a laser drilling process to expose the first portions of the first redistribution pattern, wherein the vias and the first portions of the second redistribution pattern dissipate heat accumulated on the first portions of the first redistribution pattern during the laser drilling process.

6. The method of claim 1, wherein the first portions of the first redistribution pattern have openings and wherein the openings are filled in by the second dielectric layer.

7. The method of claim 1, wherein the first portions of the second redistribution pattern have openings and wherein the openings are filled in by the third dielectric layer.

8. A method comprising:
forming a first metallization pattern on a first dielectric layer;
forming a second metallization pattern over the first metallization pattern, wherein portions of the second metallization pattern connect to portions of the first metallization pattern through vias;
forming through vias over the second metallization pattern;
attaching one or more integrated circuit dies over the second metallization pattern;
forming an encapsulant over the one or more integrated circuit dies and the through vias;
planarizing the encapsulant to simultaneously expose top surfaces of the through vias and connectors of the one or more integrated circuit dies; and
forming a front-side redistribution structure over the planarized encapsulant, the exposed through vias, and the exposed connectors of the one or more integrated circuit dies,
wherein the portions of the first metallization pattern, the vias, and the portions of the second metallization pattern form an electrically isolated thermal management system.

9. The method of claim 8, wherein forming the first metallization pattern comprises forming the first metallization pattern on a carrier substrate.

10. The method of claim 8, wherein planarizing the encapsulant comprises performing a chemical-mechanical polishing process.

11. The method of claim 8, further comprising:
forming openings in a second dielectric layer between the first metallization pattern and the second metallization pattern to partially expose the first metallization pattern.

12. The method of claim 8, wherein the one or more integrated circuit dies comprise a logic die and a memory die.

13. A method comprising:
forming a back-side redistribution structure, the back-side redistribution structure comprising:
a first metallization pattern including dummy pads, power pads, ground pads, and signal pads;
a second metallization pattern over the first metallization pattern, wherein portions of the second metallization pattern connect to the dummy pads through vias;
forming through vias over the back-side redistribution structure;
attaching a first integrated circuit die and a second integrated circuit die over the back-side redistribution structure, wherein the first and second integrated circuit dies have different functionalities;
forming an encapsulant over the first integrated circuit die, the second integrated circuit die, and the through vias;
forming a front-side redistribution structure over the encapsulant, the first integrated circuit die, the second integrated circuit die, and the through vias;
forming a back-side enhancement layer on an exposed surface of the back-side redistribution structure;
forming openings through the back-side enhancement layer using a laser drilling process to expose the dummy pads, power pads, ground pads, and signal pads; and
forming conductive connectors in the openings to contact the exposed pads,
wherein the dummy pads, the portions of the second metallization pattern, and the vias connecting them form an electrically isolated cooling system integrated in the semiconductor package.

14. The method of claim 13, wherein the first integrated circuit die comprises a logic device and the second integrated circuit die comprises a memory device.

15. The method of claim 13, wherein forming the openings through the back-side enhancement layer further comprises forming the openings through a first dielectric layer of the back-side redistribution structure.

16. The method of claim 13, wherein the back-side enhancement layer has a thickness between 25 μm and 50 μm.

17. The method of claim 13, wherein the dummy pads are disposed at corners of the semiconductor package.

18. The method of claim 13, wherein the dummy pads are disposed along opposing edges of the semiconductor package.

19. The method of claim 13, further comprising:
forming marks on portions of the back-side enhancement layer over the first integrated circuit die and the second integrated circuit die.

20. The method of claim 13, wherein the dummy pads have a diameter of 360 μm.
